(19) United States
(12) Patent Application Publication
(10) Pub. No.: US 2025/0042286 A1
(43) Pub. Date: Feb. 6, 2025

(54) EIS-BASED HEALTH-DEGRADATION HANDLING FAST-CHARGING FOR ELECTRIC VEHICLES

(71) Applicant: Garrett Transportation I Inc., Torrance, CA (US)

(72) Inventors: Semaria Ruiz Alvarez, Prague (CZ); Matej Pcolka, Prague (CZ); Gergely Takacs, Dunajská Streda (SK)

(21) Appl. No.: 18/520,155

(22) Filed: Nov. 27, 2023

Related U.S. Application Data
(60) Provisional application No. 63/517,577, filed on Aug. 3, 2023.

(51) Int. Cl. B60L 53/62; B60L 3/00; B60L 53/66; H02J 7/00

(52) U.S. Cl. CPC B60L 53/62; B60L 3/0046; B60L 53/66; H02J 7/00712; H02J 7/007194; B60L 2240/545

(57) ABSTRACT

Methods and systems for controlling fast-charging of the battery in an electric vehicle. Battery characteristics are communicated from the electric vehicle to an analyzer, which may be cloud based or may be part of a charging station. The analyzer generates temperature control signals that are communicated to the electric vehicle, and charging current control signals that are provided to charging circuitry of the charging station.

### CROSS REFERENCE TO RELATED APPLICATIONS

The present application claims the benefit of and priority to U.S. Provisional Patent Application No. 63/517,577, titled CONTROL SYSTEMS, METHODS AND DEVICES, filed on Aug. 3, 2023, the disclosure of which is incorporated herein by reference.

### BACKGROUND

Consumer demand to reduce the charge times of battery electric vehicles (BEV) has led to development of direct-current (DC) charging regimes. DC charging uses high current levels to reduce charging time until a desired battery state of charge (SOC) is reached. Various names apply, including fast-charging, quick charging, rapid charging, DC charging, Level 3 charging and others. In discussions of fast-charging, reference is made to C-rate or C, which is the charging current expressed in units of battery nominal capacity. That is, at current equal to C, the battery would reach full nominal capacity in one hour.

Most BEVs use lithium-ion batteries. High current combined with elevated temperatures may trigger a subset of degradation mechanisms in lithium-ion batteries. Examples of such include secondary electrolyte-interphase layer (SEI) formation, electrolyte drying and dissolution of the positive electrode. SEI growth phenomena cause a deposit of inert layer on electrodes by an irreversible decomposition of electrolyte components. On the other hand, charging at low temperatures and high currents may result in capacity fade due to the loss of lithium inventory by, for example, lithium plating, and power fade caused by the reduction in the porosity of the negative electrode. Lithium plating may be understood as the phenomena of metallic lithium depositing on the anode surface instead of intercalating into the electrode lattice. Different transport elements or molecules used in future chemistries may exhibit an analogous plating behavior, but in the interest of readability further discussion is limited to lithium ions; further, the below disclosed concepts are not limited to liquid electrolyte battery chemistries and may find use as well in solid electrolyte structures as those develop.

In relation to temperature, the dominating degradation mechanisms at fast-charging are paradoxical to each other. Lithium plating is to be expected at low temperatures, and SEI growth is to be expected at high temperatures. SEI growth is generally considered less damaging for the relatively short duration of the charge event. Nevertheless, these two (and other) degradation vectors are interconnected by a complex web of interactions. A further constraint arises due to safety, because if the internal temperature of the battery increases over 90° C., the volatile organic solvents present in the electrolyte can boil off the solvent, increasing the internal pressure of the battery and forcing the solvent to vent.

Many fast-charging algorithms use rigid formulae for determining charging current. For example, prior art FIG. 1 uses a constant current I_{cc} to charge the battery during a period t₁, at the end of which the battery reaches a maximum voltage. After t₁, the charger applies constant voltage at the maximum value, Vₘₐₓ, until the battery reaches a desired final state of charge, SOC_{f}, at time t₂. The right axis illustrates a comparison of anode overpotential against the Li/Li+ reference electrode, which can be seen to dip below zero after time t₁ as highlighted by the oval and reference. This indicates that electrochemical conditions are more favorable for the deposition of metallic lithium than intercalation to the anode lattice at locations with sub-zero potentials of the electrode. The degradation of the anode and thus the battery due to lithium plating continues until the anode overpotential increases to exceed zero.

Standard fast-charging according to the method illustrated in FIG. 1 has been shown to significantly reduce battery lifetime. In response, different charging profiles have been introduced. FIG. 2 shows a multi-constant current constant voltage (MCCV) profile. Here, the charger issues a first constant current, I₁, from the start of charge until t1, then at I₂ from t1 to t2, then at I₃ from t₂ until t₃, after which a constant voltage Vₘₐₓ is applied. In the illustrative profile, I₁>I₂>I₃. Other profiles, including with increases from one step to the next, may be used, and that shown is merely illustrative.

Exact functions used by various OEMs to generate charging profiles are generally not known, but indirect evidence suggests these vary substantially from one to another. U.S. Pat. No. 8,754,614 suggests a macroscopic equivalent impedance-based approach to model degradation as an all-encompassing term, using a simplified equivalent circuit to represent battery dynamics, and a look-up table to estimate battery internal equivalent resistance. U.S. Pat. No. 11,283,103 uses a complete electrochemical model to estimate the microscopic-scale battery state, from which it determines charging current to avoid degradation. These types of analyses are similarly found in other literature.

Fast-charging algorithms usually decouple temperature control. However, as noted, both temperature and current delivered to the battery affect mechanisms of degradation such as lithium plating and SEI growth. New and alternative methods for quickly charging BEV batteries are desired which can control these variables to strike a desirable balance between charging time and battery degradation.

### Overview

The present inventors have recognized, among other things, that a problem to be solved is the need for new and/or alternative methods for quickly charging BEV batteries are desired that consider both temperature and current as controlled parameters.

A first illustrative and non-limiting example takes the form of a method of controlling charging of a battery in an electric vehicle by a charging station, the method comprising the vehicle sending a set of battery parameters to an analysis system prior to charging; the analysis system using the battery parameters to calculate a target charging current profile and a target temperature profile for a charging operation; the analysis system sending a first set of temperature control signals to the vehicle; the vehicle receiving the first set of temperature control signals; with the vehicle coupled to a charging station: the charging station issuing current to the electric vehicle to charge the battery by controlling the current to match the target charging current profile; and the electric vehicle using the first set of temperature control signals to control a temperature of the battery.

Additionally or alternatively, the set of battery parameters sent by the vehicle to the analysis system includes each of an initial battery temperature, a battery state of charge, and an impedance of the battery. The impedance may be a complex impedance.

Additionally or alternatively, the method may also include the analysis system sending a second set of temperature control signals to the electric vehicle as the battery is charged; the electric vehicle receiving the second set of temperature control signals; and the electric vehicle using the second set of temperature control signals to control the temperature of the battery as the battery is being charged; wherein the electric vehicle uses the first set of temperature control signals and the second set of temperature control signals to match the target temperature profile as the battery is being charged.

Additionally or alternatively, the first set of temperature control signals includes the target temperature profile, and the electric vehicle includes a battery temperature management system which controls the temperature of the battery during charging to match the target temperature profile.

Additionally or alternatively, the analysis system calculates the target charging current profile and the target temperature profile by minimizing a sum of an estimated charge completion time and one or more penalties related to battery degradation, including at least a first penalty for lithium plating. Additionally or alternatively, the one or more penalties also includes a second penalty for solid electrolyte interphase (SEI) layer growth.

Additionally or alternatively, the analysis system is a component of the charging station. Additionally or alternatively, the analysis system is remote from the charging station, and either the electric vehicle or the charging station communicates the battery parameters to the analysis system.

Another illustrative and non-limiting example takes the form of an analyzer for determining a cycle for charging of a battery in an electric vehicle by a charging station, the analyzer comprising a controller and a controller-readable memory storing executable instructions for performing the following: receiving a set of battery parameters from the electric vehicle prior to charging; calculating a target charging current profile and a target temperature profile for a charging operation based on the set of battery parameters; sending a first set of temperature control signals to the electric vehicle based on the target temperature profile; and sending the target charging current profile to a charger controller in the charging station.

Additionally or alternatively, the set of battery parameters includes each of an initial battery temperature, a battery state of charge, and an impedance of the battery. Additionally or alternatively, the executable instructions further include an instruction for sending a second set of temperature control signals to the electric vehicle as the battery system is charged. Additionally or alternatively, the first set of temperature control signals includes the target temperature profile for use by the electric vehicle to control the temperature of the battery during charging.

Additionally or alternatively, the executable instructions further include instructions for calculating the target charging current profile and the target temperature profile by: calculating one or more penalties determined for each of a plurality of charging steps, including at least a first penalty for lithium plating; and minimizing a sum of an estimated charge completion time and the one or more penalties by manipulating charging current to be delivered in each of the plurality of charging steps.

Additionally or alternatively, wherein the one or more penalties also includes a second penalty for SEI layer growth. Additionally or alternatively, the first penalty is determined from a data table using temperature of the battery system, charging current, and state of charge, and the second penalty is determined from a data table using temperature of the battery system, charging current, and state of charge. Additionally or alternatively, the first penalty is an explicit function of temperature of the battery system, charging current, and state of charge.

Additionally or alternatively, the analyzer is part of a remote server located away from the charging station, and the executable instructions are for sending the target charging current profile to a charger controller in the charging station by communicating remotely to the charger controller.

Another illustrative and non-limiting example takes the form of a charging system for an electric vehicle having therein a battery, the charging system comprising a charging architecture having a charging controller, and an analyzer as in the preceding examples.

Another illustrative and non-limiting example takes the form of an electric vehicle comprising: a battery for providing driving power to the electric vehicle; a battery thermal management system (BTMS); and an electrochemical impedance spectroscopy (EIS) diagnostic system for performing EIS on the battery to obtain a complex impedance thereof; a controller configured to: control the EIS diagnostic system to perform EIS on the battery to determine a complex impedance of the battery; in anticipation of a charging event at a charging station, send the complex impedance, a state of charge of the battery, and a temperature of the battery to an analyzer; receive, from the analyzer one or more temperature control instructions; control the BTMS to execute the one or more temperature control instructions during charging of the battery at the charging station.

Additionally or alternatively, the controller is further configured to: control the BTMS to adjust the battery temperature to match a first temperature in the one or more temperature control instructions; determine the battery is at the first temperature; and issue a communication to the charge station indicating that the battery is ready for charging.

This overview is intended to provide an introduction to the subject matter of the present patent application. It is not intended to provide an exclusive or exhaustive explanation. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1-2 show illustrative prior art fast-charging profiles for BEVs;

FIG. 3 shows a simplified BEV;

FIG. 4 shows a battery cooling system;

FIG. 5 shows a battery diagnostic system;

FIGS. 6A-6B show two architectures for BEV battery charging;

FIG. 7 illustrate a battery equivalent resistance circuit model;

FIG. 8 shows several battery charging curves;

FIG. 9 shows how an impedance penalty can be determined; and

FIG. 10 shows a battery charging profile and a temperature profile for an illustrative example.

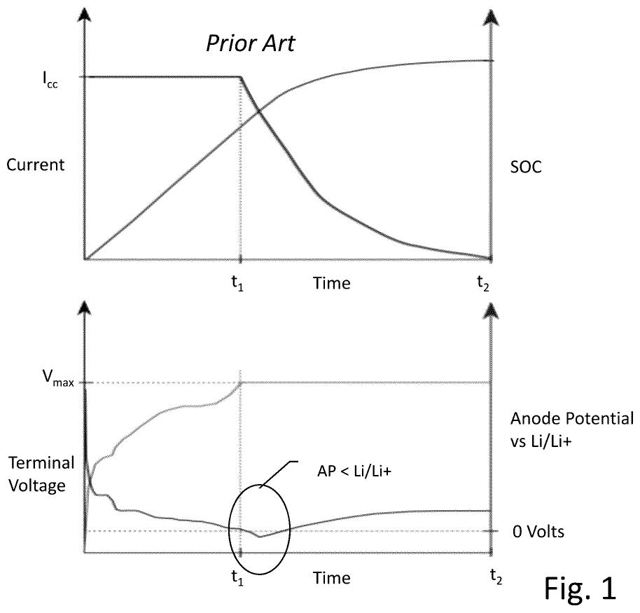

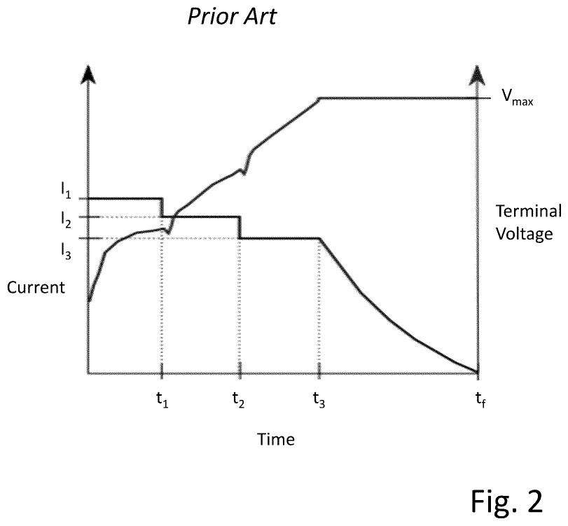

### DETAILED DESCRIPTION

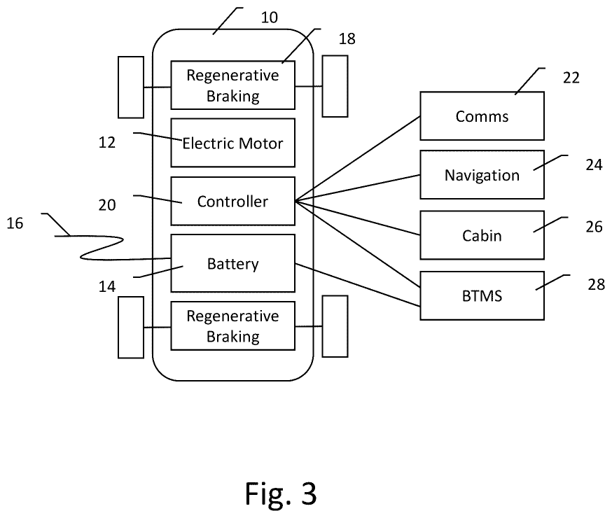

In several illustrative examples, alternatives to and improvements upon the prior art fast-charging profiles for BEVs are disclosed. To provide context, first various elements of the system are discussed. FIG. 3 shows a simplified BEV mainly in block form. A skilled person will recognize that the following discussion may not necessarily describe every feature that would be present in the vehicle 10, to avoid excessive exposition of features that are not necessary to understand the following examples.

The vehicle 10 is characterized by an electric motor 12 (or plural electric motors 12) that provide driving force to the vehicle 10, powered by a battery 14 through a voltage source converter (not shown). The battery 14 may take the form of a battery pack comprising a number of battery cells. The battery 14 is rechargeable by connection 16 to an off-vehicle electricity source, as is known in the art, and may have any suitable chemistry and/or design. Battery 14 is connected to warming and/or cooling apparatuses to maintain suitable temperatures therein, as further explained below. Regenerative braking 18 may be provided, and serves to at least partly recharge the battery 14 under suitable braking conditions. Though BEVs are the main focus of this discussion, the enhancements discussed herein may also apply, for example, to plug-in hybrid vehicles, for which an engine (not shown) may be included, such as an internal combustion engine. In the appended claims, a battery-electric vehicle, or an electric vehicle, indicates any of a hybrid vehicle having two power systems including at least one that uses a motor and battery, or an electric-only vehicle lacking a second power source/system.

A controller 20 is coupled to each of these blocks, and may further be linked to control blocks for communications 22, navigation 24, infotainment (not shown), and cabin 26. The controller 20 is configured for sending and receiving information as well as to provide and/or control power used by, for example, an air conditioning unit used for cooling the cabin 26, or other environmental controls for the cabin 26. There may be additional controllers located within each of the blocks shown; for example, as described below, a battery management system (BMS) provides control for the battery 14.

The controller 20 (and other controllers in the system, including in the BMS) may take many forms, including, for example, a microcontroller or microprocessor, coupled to a memory storing readable instructions for performing methods as described herein, as well as providing configuration of the controller 20 for the various examples that follow. A controller 20 may include one more application-specific integrated circuits (ASIC) to provide additional or specialized functionality, such as, without limitation a signal processing ASIC that can filter received signals from one or more sensors using digital filtering techniques. Logic circuitry, state machines, and discrete or integrated circuit components may be included. A skilled person will recognize many different hardware implementations are available for a controller 20. The controller 20 may be part of a computer (desktop, laptop, etc.) provided as part of the overall system. The controller 20 may include, be part of, or communicate with an advanced control framework as disclosed in U.S. patent application Ser. No. 17/241,668, filed Apr. 27, 2021 and titled ADVANCED CONTROL FRAMEWORK FOR AUTOMOTIVE SYSTEMS, the disclosure of which is incorporated herein by reference.

Communications 22 may include any of satellite, cellular, Bluetooth, broadband, WiFi, and/or various other wireless communications circuits, antennae, receivers, transceivers, transmitters, etc., as desired. The communications 22 may allow the controller 20 to send and receive data relative to one or more internet, dedicated, and/or cloud-based data receiving and/or processing centers, such as a fleet monitor. The communications 22 may be used to upload and/or download data of various types.

The navigation system 24 may store, retrieve, receive, and/or display various types of data including, for example and without limitation, weather/environmental data, road data including curvature, posted speed limits, and grade, as well as traffic data, as desired. The navigation system 24 may also be used to provide route instructions to a driver of the vehicle, and/or to provide a route for an autonomous drive controller to use. The navigation system 24 may include a global positioning system (GPS) device for determining and tracking position of the vehicle 10.

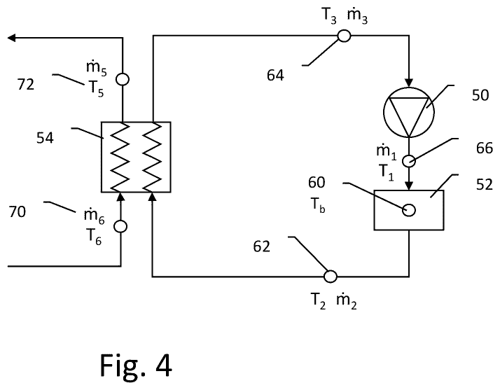

A battery thermal management system (BTMS) 28, is also shown. The BTMS controls temperatures in the battery 14 using a cooling system as shown in FIG. 4, for example, and may receive control signals from the controller 20. The BTMS can be implemented with an additional controller and the various componentry shown and/or described below, and/or with other thermal control systems.

FIG. 4 shows a battery cooling system. A circulating fluid passes through the loop on the right side of FIG. 4, with a pump 50 pushing the mass flow through the system into the battery 52, and chiller 54. Various sensors may be placed to sense one or more of temperature and/or mass flow of the circulating fluid, including the battery temperature T_{b} at 60, as well as at locations 62, 64, and 66, as desired. There may be multiple battery temperature sensors 60, if desired. The chiller 54 provides heat exchange with a refrigerant which also circulates in its own loop, with, as desired, sensors for temperature and/or mass flow entering and leaving the chiller 54, as indicated at 70, 72. For example, the refrigerant may circulate in a vapor compression cycle, if desired. While not shown in FIG. 4, a heater may be included, as well as valves to divert the circulating fluid from the chiller to a heater for warming the battery 52, and there may be further fluid management to support heating and cooling to other systems including the inverter, motor and/or cabin. The battery temperature is controlled by managing, for example, pump 50 speed as well as the temperature and mass flow of refrigerant through the chiller 54, among other parameters. Such control over battery temperature can be aided by measuring or modelling the circulating fluid mass flow and temperatures.

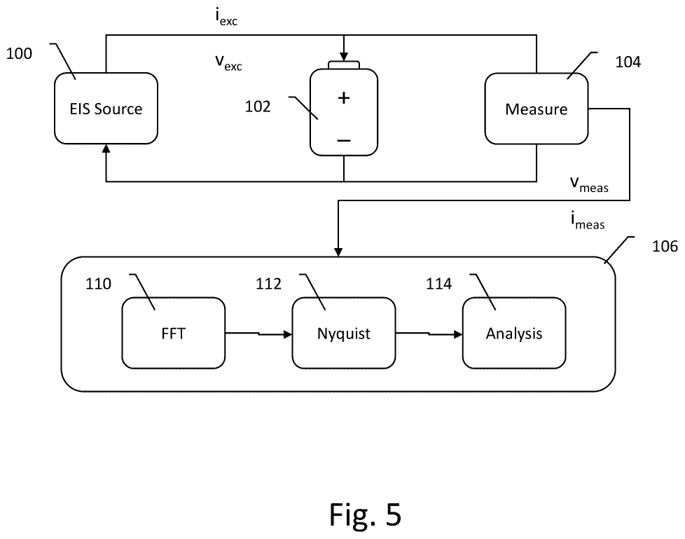

FIG. 5 shows a battery diagnostic system. An electrochemical impedance spectroscopy (EIS) source 100 provides an excitation signal to a battery 102. The illustrated diagnostic system may be contained in an electric vehicle as shown in FIG. 3. The excitation signal may be an excitation current, i_{exc} or an excitation voltage v_{exc}. The signal applied is an alternating signal, having a frequency. Measurements of the battery 102 response to the excitation signal are performed by block 104. If the excitation signal is an excitation current, i_{exc}, a measured voltage, vₘₑₐₛ, is obtained; if the excitation signal is an excitation voltage v_{exc}, a measured current iₘₑₐₛ is obtained. The measurement 104 occurs as the EIS source 100 sweeps through several frequencies or a range of frequencies of excitation signal.

Characteristics of the excitation signal and measured signal are passed to an EIS analysis block 106. A fast Fourier transform (FFT) is performed at 110, and the results populate a plot 112 (shown as a Nyquist plot, which is a parametric plot of a frequency response, but any suitable frequency response analysis may be used). In this process, the complex impedance of a battery cell or set of battery cells (or the entire battery) may be calculated from the current and/or voltage measurement across the frequency sweep. The results are analyzed at block 114. Reading EIS across an entire battery of a BEV may be less useful than reading EIS for each of the battery cells individually or in small groups, increasing granularity of the measurement.

The analysis at block 114 may take several forms. For example, analysis 114 may simply be to compare parameters, FFT results, etc., across a block of similarly situated battery cells to identify any outliers, indicative of possible failure of any outlier battery cells. If there are no outliers, the battery cells may be deemed operational. Analysis 114 may compare each battery cell to stored empirical data based on battery cells from controlled or laboratory testing, to determine whether battery cells are performing and/or aging appropriately.

Analysis 114 may instead be used to determine the current state of a battery cell, such as the SOC. For example, with at least some battery chemistries, an open circuit voltage (OCV) measurement may correspond to a wide range of possible SOC. At a given OCV, however, the response to EIS may narrow the range of possible SOC, depending on chemistry, for example. For the purpose of determining SOC, controlled laboratory testing may be used to generate data to which the EIS data can be compared in block 114. EIS may be highly useful for this purpose because EIS enables insight into the internal electrochemical processes and allows ohmic resistance, charge transfer resistance and double layer capacitance, among other characteristics, to be at least indirectly observed. If a lithium chemistry is used in the battery cell, for example, the EIS may also provide an understanding of lithium plating characteristics and/or SEI formation. One challenge for use in a vehicle is finding ways to perform EIS that use minimal power without being cost prohibitive.

An onboard EIS system addressing the power issue for a vehicle is disclosed, for example, in U.S. patent application Ser. No. 18/498,996, filed Oct. 31, 2023, titled SYSTEM AND METHOD FOR ONLINE ELECTROCHEMICAL IMPEDANCE SPECTROSCOPY MEASUREMENT IN A BATTERY, the disclosure of which is incorporated herein by reference. Other EIS designs may be used.

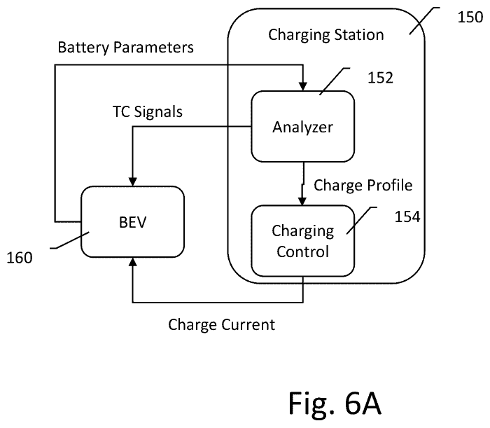

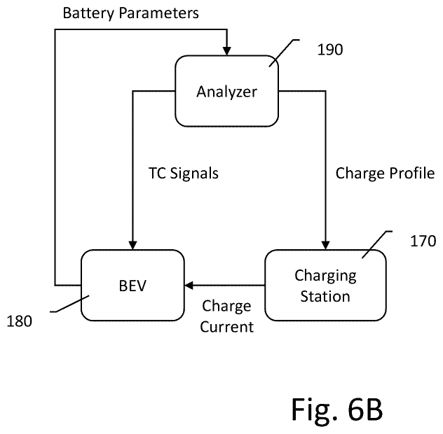

FIGS. 6A-6B show two architectures for BEV battery charging. In FIG. 6A, a charging station 150 has an analyzer block 152 and a charging control block 154, and is shown relative to a BEV 160. The BEV 160 provides a set of battery parameters to the charging station 150, and more particularly to the analyzer 152. The analyzer 152 determines a set of temperature control signals that are communicated back to the electric vehicle 160, and a charge profile which is communicated to the charging controller 154. The charge profile may be communicated for example, in the form of the entire calculated charge profile to the charging controller 154, or as a series of control signals to the charging controller 154 such that the series of control signals causes the charging controller to generate charging current in accordance with the charge profile.

The charging controller 154 then supplies charge current to the BEV 160, tracking the charge profile from the analyzer 152. A complete profile can be communicated by the analyzer 152 to each of the BEV 160 and the charging control 154 in some examples. In other examples, the analyzer 152 communicates a number of control signals over time as the charging of the BEV 160 progresses. The battery parameters that are communicated to the analyzer 152 may include a measured/latest SOC, open circuit voltage (OCV) and temperature of the battery, type of battery, battery architecture, and/or vehicle, and aging or state data related to the battery, which may include the EIS characterization of the battery. As charging is performed, particularly if the analyzer 152 is providing ongoing control signals, the battery temperature, OCV, SOC, and/or other parameters may be updated and communicated over time.

FIG. 6B shows another illustrative architecture. Here, the analyzer 190 is remote from both the BEV 180 and the charging station 170. For example, the analyzer 190 may be a cloud-based or otherwise remote server, communicating with the charging station 170 and BEV 180 by any suitable communications methods. In other respects, the system operates generally the same as in FIG. 6A. In another example, the BEV 180 may communicate the battery parameters to the charging station 170 which in turn communicates the battery parameters to the analyzer 190, and the temperature control signals are in turn routed form the analyzer 190 to the charging station 170 and then to the BEV, such that the BEV 180 only communicates with the charging station 170. For such an example, the BEV 180 may send battery parameters to the analyzer 190 via the charging station 170, and the analyzer 190 may send the temperature control signals to the BEV 180 via the charging station 170. Other communication combinations may be used.

In some illustrative examples, the BEV 160, 180 includes, as illustrated in FIG. 3, a battery for providing driving power to the electric vehicle, and a battery thermal management system (BTMS). The BTMS may include a cooling system as in FIG. 4, or another configuration, which may also include a heater if desired for warming the battery as needed. Further, the BEV 160, 180 also includes, in several examples, an electrochemical impedance spectroscopy (EIS) diagnostic system for performing EIS on the battery to obtain a complex impedance, such as shown in FIG. 5. The controller of the illustrative electric vehicle is configured to control the EIS diagnostic system to perform EIS on the battery to determine a complex impedance of the battery. Moreover, in anticipation of a charging event at a charging station, the controller sends the complex impedance, a state of charge of the battery, and a temperature of the battery to an analyzer, and to receive from the analyzer one or more temperature control instructions, as illustrated in either of FIGS. 6A-6B. The controller then uses the BTMS to execute the one or more temperature control instructions during charging of the battery at the charging station. For example, if the battery is determined to be at an SOC below a threshold (e.g. 20 to 30% of maximum) and the electric vehicle is approaching a fast-charging station (capable of more than, for example, 2C to 4C charge currents), or if the driver indicates that a recharge is about to occur (or if an autonomous vehicle, if the autonomous controller determines to charge the system), the electric vehicle may start thermal pre-conditioning of the battery.

The system may also be used to condition the electric vehicle for charging. In an example, the controller is further configured to control the BTMS to adjust the battery temperature to match a first temperature in the one or more temperature control instructions prior to charging beginning. When the controller determines the battery is at the first temperature, charging can commence. In some examples, the pre-conditioning may take place while the vehicle is being driven to the charging station, or while waiting at or entering the charging station, if desired. In some examples, pre-conditioning may take place at the charging station, for example, after the vehicle has been connected to the charging station, the charging station may wait for an indication that charging can begin, as the battery is brought to a desired temperature. Optionally, the electric vehicle or controller thereof may issue a communication to the charge station indicating that the battery is ready for charging, and charging then begins. If desired, power for cooling the battery may be obtained from the charging station itself, rather than drawing such current from the battery which would cause resistive heating of the battery.

It should be noted that in each of FIGS. 6A and 6B, the temperature profile or temperature commands are provided to the BEV from the analyzer, which also generates the profile or commands for the charging station to output charge currents and voltages (collectively, charging power) over time. The temperature control and charging power can therefore be provided in synchronized manner, using methods and providing results as illustrated further below.

The analyzer is configured to set the temperature and charging power commands to minimize charging time of the battery, while minimizing fast-charging degradation that is predominantly caused by lithium plating and SEI growth, or at least keeping such degradation within chosen acceptable limits. This is achieved through the calculation of temperature and current profiles that should be kept during the charging process. A multi-constant current constant voltage charging profile is assumed, while an equivalent-circuit model (ECM) with specific elements associated to electrochemical phenomena through electrochemical impedance spectroscopy (EIS) is employed to predict voltage response and instantaneous degradation state of the battery.

The analyzer in either of FIGS. 6A-6B may be implemented as a controller configured to perform the optimization procedures disclosed herein. For example, analyzer 152 may operate by executing a set of stored software instructions for calculating and sending or communicating the temperature control signals to the BEV, and calculating and sending or communicating the charge profile or charging control signals to the charging controller 154 (FIG. 6A). For example, analyzer 190 may operate by executing a set of stored software instructions for calculating and sending or communicating the temperature control signals and charge profile to the BEV and Charging Station (FIG. 6B).

In some examples, the optimization balances charging time and health degradation of the battery. Weights or penalties may be associated with increases in either of charging time or degradation in the optimization, such that a cost minimization approach can be used. Other examples may optimize charging time by constraining total instantaneous degradation of the battery (or degradation for each current step) to below chosen value.

First, an optimization procedure that balances charging time and health degradation of the battery will be illustrated. The target charging current I_{cc,i} and temperature profile T_{b,i}, for each discrete time instance, tᵢ, is determined in the optimization, so that a weighted combination of charging time and health degradation is minimized. Battery characteristics communicated from the BEV to the analyzer (FIGS. 6A-6B) include the EIS characterization of the BEV battery. Alternatively, the BEV battery type or vehicle type may be communicated to the analyzer, which can rely on predefined EIS characterizations for the particular battery or vehicle type from a database.

A cost function can be constructed as shown in Equation 1:

$$g ( {\{ {I}_{cc} \}}_{i} , {\{ {T}_{b} \}}_{i} , {\{ t \}}_{i} , N ) = {min}_{{\{ {I}_{cc} \}}_{i} , {\{ {T}_{b} \}}_{i} , {\{ t \}}_{i} , N} ( {t}_{f} + {\sum }_{i = 1}^{N} {w}_{HD , i} \cdot {f}_{HD , i} ( {I}_{cc , i} , SOC ( {t}_{i} ) , {T}_{b , i} ) ) \qquad ( 1 )$$

Where N is the number of steps in the charging profile (and may be optimizable as part of the analysis), I_{cc} is a vector in the real number space that contains magnitudes of current in the N constant-current steps, and I_{cc,i} is the value of the current I(t) at the i^{th} step. For this purpose, the relationship between the current steps and time slots is given by:

$${I}_{cc , 1} = I ( t \vert t ∈ [ 0 , {t}_{1} ) )$$

$${I}_{cc , 2} = I ( t \vert t ∈ [ {t}_{1} , {t}_{2} ) )$$

$$…$$

$${I}_{cc , N} = I ( t \vert t ∈ [ {t}_{N - 1} , {t}_{N} ] )$$

Also in equation 1, Tb is a vector in the real number space that contains the magnitudes of the N battery temperature set points, that is, one set-point per one current step (for this first optimization procedure; in the second optimization below, there may be more than one temperature in each current step). SOC(tᵢ) is the state of charge of the battery at the time instance tᵢ. In addition, w_{HD,i} is a weighting factor or the importance given to the function f_{HD,i}, that represents the battery degradation corresponding to the i^{th} time interval. The function, f_{HD,i}, may be a sum of penalties for one or more different types of battery degradation. The degradation function in some examples has only one term, for lithium plating; in other examples, the degradation function may sum each of a term for lithium plating and one for SEI layer characteristics. The term t_{f}=t_{N} is the charging time at which the SOC condition shown here must be accomplished:

SOC(t_{f})=SOC_{target}

That is, the battery SOC at the end of the charging period is equal to the target SOC. The target SOC may be, for example, 80% of battery total SOC if desired, though other targets can be set.

The terminal voltage, over time, must meet this requirement as well:

Vₜ(t)≤Vₘₐₓ

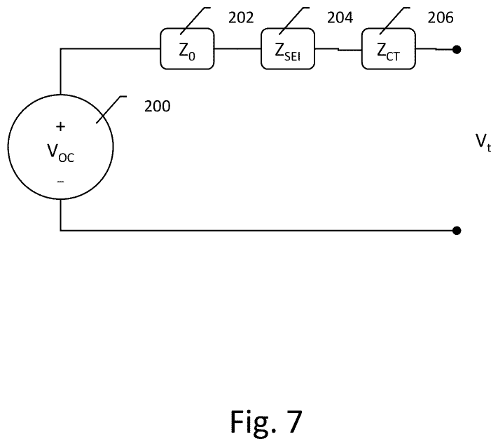

This rule ensures that terminal voltage is kept lower than the maximum allowed, Vₘₐₓ, during the charging period. The terminal voltage may be estimated from the equivalent circuit shown in FIG. 7.

FIG. 7 illustrates a battery equivalent resistance circuit model. The battery open circuit voltage (V_{OC}) 200 is a function of the battery SOC. V_{OC} 200 relates to a terminal voltage, Vₜ, after current flow passes through each of three impedances: Z₀ 202, which is the catchall for internal impedance of the battery not counted in the next two terms, Z_{SEI}204, which is the impedance related to SEI layer characteristics, and Z_{CT} 206, which is the charge transfer resistance that indirectly correlates to lithium plating phenomenon. The model considered above is a form of an equivalent-circuit model, where instead of an abstract R—C element (or a chain) fit to an electric response in the time-domain, each impedance component is indirectly associated to a group of electrochemical phenomena and can be inspected or measured using EIS. In essence, the model is then an electrochemical-phenomena aware augmented equivalent circuit model that may capture dominant short-term changes that are indirectly associated with degradation phenomena.

The impedances Z₀ 202, Z_{SEI} 204, and Z_{CT} 206 are functions of one or more of charging current, battery temperature, SOC, and battery state of health (SOH), where SOH includes effects of each of SEI growth and lithium plating, among other factors. The EIS diagnostics can readily identify each of the impedances Z₀ 202, Z_{SEI} 204, and Z_{CT} 206.

Lithium plating and SEI growth that be avoided if the impedances Z_{SEI}, and Z_{CT} are kept between safe margins, shown below as Z̅_{CT}, and Z̅_{SEI}. A function, f_{HD,i} that specifies the battery health degradation can be defined as the total overshoot of the defined safe margins, as shown in Equation 2:

$${\sum }_{i = 1}^{N} {f}_{HD , i} ( {I}_{CC , i} , SOC ( {t}_{i} ) , {T}_{b , i} ) = {\sum }_{i = 1}^{N} ( {t}_{i} - {t}_{i - 1} ) \cdot [ max ( {Z}_{CT} ( {I}_{cc , i} , SOC ( {t}_{i} ) , {T}_{b , i} ) - {\overline{Z}}_{CT} ( {I}_{cc , i} , SOC ( {t}_{i} ) , {T}_{b , i} ) , 0 ) + max ( {Z}_{SEI} ( {I}_{cc , i} , SOC ( {t}_{i} ) , {T}_{b , i} ) - {\overline{Z}}_{SEI} ( {I}_{cc , i} , SOC ( {t}_{i} ) , {T}_{b , i} ) , 0 ) ] \qquad ( 2 )$$

Here, the impedances Z_{SEI}, and Z_{CT} are expressed and characterized as explicit functions of the constant current, SOC, battery temperature, and SOH. Alternatively, look up tables can be used, based for example on battery age. With either explicit functions or look up tables, the EIS data can be used as input for this characterization procedure. The look-up table data or explicit functions, whichever is used, may be determined from empirical testing of battery cells undergoing charging in controlled conditions. Explicit functions may be continuous or may have piece-wise components matching different portions of the data, such as for different temperatures, SOC, and/or charging current, as desired. Each of temperature, SOC, and charging current can be inputs to the look-up tables or explicit functions.

The SEI growth safe level, Z̅_{SEI} is defined according to the maximum allowed degradation with the EIS data characterization of the battery, considering that a high value of Z̅_{SEI} implies a higher degradation.

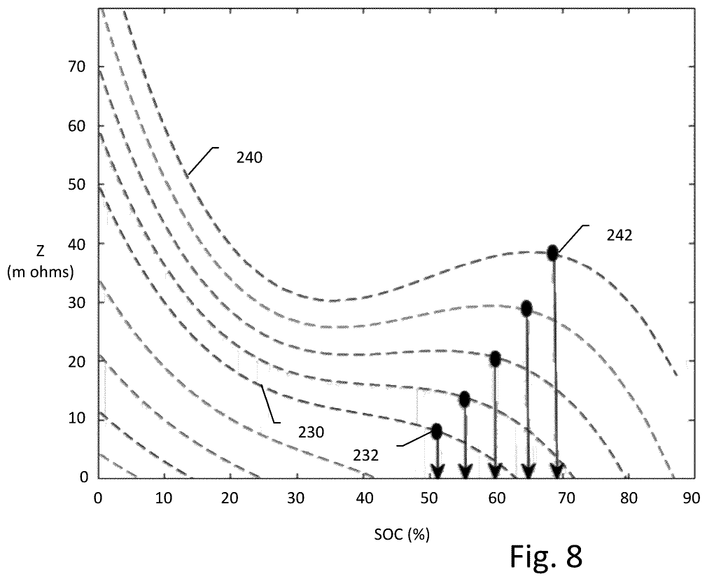

FIG. 8 shows several battery curves, based on data for an illustrative Nickel-Cobalt-Aluminum (NCA) battery cell having a 3.1 Amp-Hour capacity. A safe level of Z̅_{CT}, relating to lithium plating, is defined as the inflection point of the charge transfer resistances mapped for static SOC-dependent charging tests, as FIG. 8 shows. More particularly, FIG. 8 shows a plurality of curves, such as those at 230 and 240, each representing a different charging current while the battery temperature and state of health are fixed. The impedance experienced by each curve changes with state of charge of the battery, as process dynamics change during charging. Curve 230, for example, may be at 5C (five times the current that would be required to charge from 0% SOC to 100% SOC in an hour), and curve 240 may be at 1.5C. Vertical arrow 232 indicate the SOC at which charging using curve 230 (5C) would experience start of lithium plating. At lower current line 240, lithium plating may begin at a lower SOC, as indicated at 242. As the concentration changes of lithium ions waiting to be intercalated at the particle interface is a dynamic phenomenon, Z̅_{CT} may include or be adjusted for a safety margin to account for the difference between the test and reality. The curves in this illustrative example may change based on factors other than the charge current, such as battery temperature and degradation level expressed by an SOH term.

The safe level for SEI growth, Z̅_{SEI}, may be defined as a constant, a vector, or a function of SOC level, battery temperature, charging current, and/or other factors suitable to the particular battery and implementation. However, there is more freedom relative to Z̅_{CT}, which should be expressed as a function of SOC, charging current, battery temperature, and, in some examples, SOH estimated from EIS data. During a fast-charging regime, the dominant degradation phenomena can be expected to arise from lithium plating, and hence Z̅_{CT} can be used as the limit value.

Referring back to Equation 1, the health degradation factor, f_{HD,i}, is multiplied by a weight factor, w_{HD,i}. Any suitable setting of w_{HD,i} may be used, for example, the weight may be a pre-defined value, such as a fixed value, or may vary such as by rising over time within a given charging iteration. The weight factor may be set using environmental conditions if desired. Using this weight factor, then, the fast-charging cost function will penalize the total overshoot area of SEI and CT impedances relative to their identified safe levels.

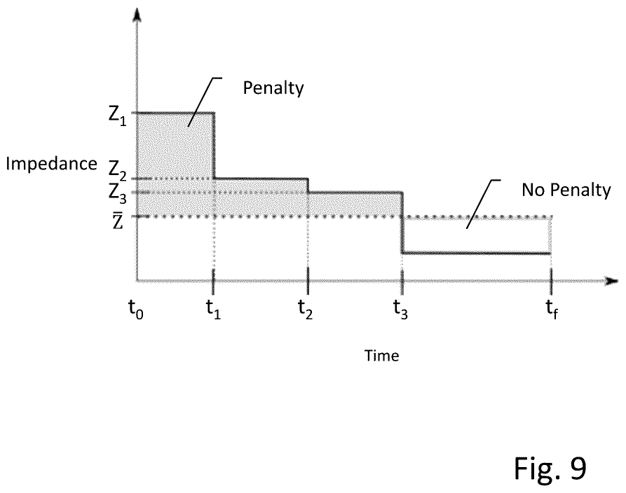

FIG. 9 shows how an impedance penalty can be determined using these concepts.

As noted above, the charging model may be for multi-constant current constant voltage (MCCV), so that several time periods (t₀ to t₁, t₁ to t₂, t₂ to t₃, and t₃ to t_{f}) are defined along the horizontal axis. The estimated or calculated impedance, given a charging current level and other conditions (temperature, battery SOH, SOC, etc.) is shown for each time period on the horizontal axis. The penalty can be understood as the area above Z̅ in each such time period, marked “Penalty” on the Figure. When the impedance is below Z̅, as happens in the last time period shown, no penalty applies.

It should be noted that the battery SOC and terminal voltage are two dynamic variables in the optimization. In some examples the evolution of each of SOC and terminal voltage may be calculated only at the time points when current changes, that is, at t₀, t₁, t₂, etc, but are treated analytically as constants within each time interval, [tᵢ₋₁, tᵢ]. This need not be the case, and other, more complex modeling or time-updating models may be used. Given the assumption of SOC and terminal voltage only being calculated at transitions of the current level, additional constraints are needed to avoid over- or under-estimation of impedance, open circuit voltage (and in consequence, terminal voltage), each of which are dependent on the constant current value, temperature, and SOC.

First, the SOC at the end of each constant current interval can be determined as shown in Equation 3:

$$SOC ( {t}_{i} ) = SOC ( {t}_{i - 1} ) + {p}_{SOC} {I}_{cc , i} \cdot ( {t}_{i} - {t}_{i - 1} ) \qquad ( 3 )$$

Here, p_{SOC} is a coefficient representing the influence of the charging current, I_{cc,i} on the battery SOC. For example, p_{SOC} may be as shown here:

$${p}_{SOC} = \frac{1}{3 \; 600 {C}_{b}}$$

Where C_{b} is the battery nominal capacity in Amp-Hours. Other formulas may be used, if desired, and, can be directly estimated from time series data of SOC and I_{cc}, where SOC is inferred from a measured terminal voltage on the battery, for example.

Terminal voltage at the end of each constant current time interval may be calculated using Equation 4:

$${V}_{t} ( {t}_{i} ) = {V}_{oc} ( SOC ( {t}_{i} ) , {T}_{b , i} ) + {Z}_{0 , i} \cdot {I}_{cc , i} + {V}_{SEI} ( SOC ( {t}_{i} ) , {T}_{b , i} , {I}_{c c , i} ) + {V}_{CT} ( SOC ( {t}_{i} ) , {T}_{b , i} , {I}_{cc , i} ) \qquad ( 4 )$$

Where V_{OC} represents open-circuit voltage, and Z_{0,i}·I_{cc,i} is the voltage over the internal impedance of the battery caused by the charging current. It should be noted that internal impedance of the battery may also be variable expressed as a function of SOC and battery temperature: Z_{0,i}=Z₀(SOC(tᵢ),T_{b,i}). Next, V_{SEI}(SOC(tᵢ),T_{b,i},I_{cci}) is the voltage over the impedance related with SEI growth at the battery temperature and charging current. Finally, V_{CT}(SOC(tᵢ),T_{b,i},I_{cci}) is the voltage over the charge transfer impedance related to lithium plating and other factors, at the battery temperature and charging current.

For simplification, it may be assumed that the internal impedance of the battery can be approximated by only its resistive part, and that the SEI and charge transfer impedances can be approximated at RC branches with pure capacitance. Then, the voltage drop for the charge transfer impedance can be calculated as shown in Equation 5:

$${V}_{CT} ( {t}_{i} ) = ( {V}_{CT} ( {t}_{i - 1} ) - {I}_{cc , i} \cdot {R}_{CT , i} ) \cdot {e}^{- \frac{( {t}_{i} - {t}_{i - 1} )}{{R}_{CT , i} \cdot {C}_{CT , i}}} + {I}_{cc , i} \cdot {R}_{CT , i} \qquad ( 5 )$$

In Equation 5, R_{CT,i} represents the resistance of the charge transfer impedance at the time instance tᵢ, and may be specified as a function of battery SOC, battery temperature, and charging current. That is, for example:

R_{CT,i}=R_{CT}(SOC(tᵢ),T_{b,i},I_{cc,i})

Also, C_{CT,i}, the capacitive part of the charge transfer impedance may be a function of the same variables:

C_{CT,i}=C_{CT}(SOC(tᵢ),T_{b,i},I_{cc,i})

The resistive and capacitive components of SEI impedance may be likewise characterized. Each of these impedance characterizations may be based on battery testing, including life/aging testing as well as characterization under load and charging, to determine the correct relationships (quadratic, linear, etc.) among the variables, as well as internal coefficients. Each may be a continuous function, multiple functions, or stored look-up table data may be used, for example and without limitation.

As noted, in some examples, MCCV charging is used, and the evolution of each of SOC and terminal voltage is only updated at the end of the constant current time intervals in the MCCV. To support accuracy, the duration of each time slot may be limited:

$${t}_{i} - {t}_{i - 1} \leq Δ {t}_{max} \qquad ( 6 )$$

Where Δtₘₐₓ is the maximum time difference for which variations of the circuit parameters and terminal voltage, with respect to the SOC, battery temperature and current, can be considered negligible. The actual value may vary with the particular vehicle, battery and charger capabilities, but can be expected to be in the range of up to a few minutes, such as in the range of about 1 to 10 minutes. This maximum time may be applied on a sliding scale in relation to V_{OC} and/or battery SOC, since, for example, at lower SOC (and hence V_{OC}), the terminal voltage may change more quickly starting from a low value as well as when operated under high currents. In other examples, the maximum time difference may be determined by using a maximum charge delivery formula, meaning that shorter maximum times would apply to higher current steps. Other suitable formulations may be used.

The temperature of the battery in the BEV is controlled by a battery thermal management system (BTMS), as described previously. The battery temperature can affect each of the preceding elements of the method and system. The time delay of the battery thermal behavior, and the initial temperature before a charging event are, in some examples, also included as a temperature constraint:

$${T}_{min , i} \leq {T}_{bi} \leq {T}_{max , i} ;$$

$$\vert {T}_{bi} - {T}_{b i - 1} \vert \leq Δ {T}_{max}$$

$${T}_{b 0} = {T}_{initial}$$

In this set of constraints and initialization, the minimum temperature T_{min,i}, maximum temperature T_{max,i}, and the maximum temperature change ΔTₘₐₓ for each constant current step should be determined according to the capability of the BTMS to remove heat from the battery, as well as the time delay of the thermal system and the initial temperature (Tᵢₙᵢₜᵢₐₗ) of the battery before the charging event.

In the preceding example, the desired battery temperature may be communicated from the Analyzer to the BEV for use by the BTMS of the BEV to control battery temperature during each stage of the charging process. In some examples, the BTMS may be instructed to hold a particular temperature during an entire constant current step, except to the extent that a different temperature may be requested for a subsequent step. To transition from one step to the next, the BTMS may receive a new temperature setpoint or set of commands in anticipation of the next stage of constant current (or constant voltage) charging, if desired.

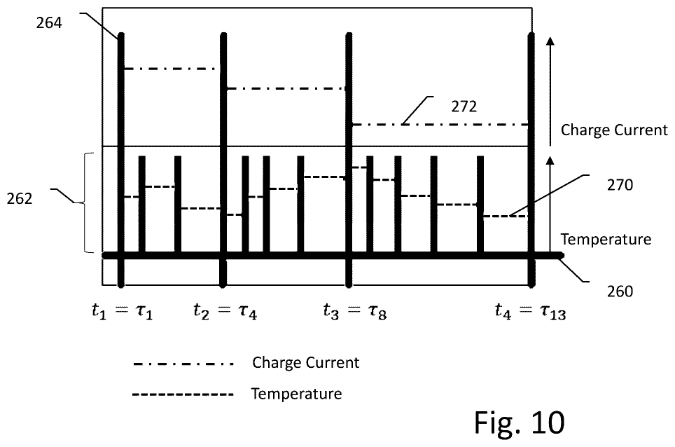

A further example is highlighted with FIG. 10, which shows a battery charging profile for an illustrative example. Here, two sets of time steps are involved. The times t1, t2, t3, and t4 each indicate transition points in the MCCV charging procedure. The times {τ1 . . . τ13}represent time steps of the BTMS temperature control over the battery. As can be seen, the time steps may have different sizes. That is, timeline 260 has minor ticks 262 for the BTMS control, spanning {τ1 . . . τ13}, and major ticks 264 for the MCCV charging settings. Thus, the temperature is controlled as indicated at 270, changing as commanded to provide optimized outcomes during charging, avoiding health impacts without unduly slowing charging. Meanwhile, current is controlled as indicated at 272.

With FIG. 10, the battery temperature is set as a dynamic variable, though with a different time scale than that applied for current. As a general case, this new “micro-scale” considers discretize time samples τⱼ, where j ranges from 1 to M, and M is the overall quantity of micro-steps included in all N macro-steps. Then each of τ_{M} and t_{N} are the end time of the operation, such that τ_{M}=t_{N}=t_{f} and:

$$∀ j ∈ \{ 2 , … , M \} \text{:} ( {τ}_{j} - {τ}_{j - 1} ) \leq {min}_{i ∈ \{ 2 , .. N \}} \{ ( {t}_{i} - {t}_{i - 1} ) \}$$

This constraint ensures that the duration of any of the temperature related time intervals is shorter than the duration of any of the constant current related time intervals, meaning that temperature is discretized in a finer manner than current. Further, the time scales may be chosen in some examples so that each coincides at the end of each of the constant current related time intervals, as shown in FIG. 10. This may be expressed as:

∀i∈{1,2, . . . ,N},∃j∈{1,2, . . . ,M}:tᵢ=τⱼ

That is, for every time instance, tᵢ, there must be a corresponding time instance τⱼ. This additional constraint may be omitted in some examples, as desired. The number of time instances used in each time scale may be treated as an optimizable variable.

Equation 1 may be modified using an additional variable, Tᵢₙₗ, the circulating fluid temperature at the battery inlet in the BTMS. The evolution of battery temperature, SOC, and battery terminal voltage may be modelled as shown in Equations 7-9:

$$SOC ( {τ}_{j} ) = SOC ( {τ}_{j - 1} ) + {p}_{SOC} {I}_{cc , i} \cdot ( {τ}_{j} - {τ}_{j - 1} ) \qquad ( 7 )$$

$${T}_{b} ( {τ}_{j} ) = {T}_{b} ( {τ}_{j - 1} ) + ( {τ}_{j} - {τ}_{j - 1} ) \cdot ( a \cdot {T}_{b} ( {τ}_{j - 1} ) + b \cdot {T}_{inl , j} + c \cdot {I}_{cc , i}^{2} ) \qquad ( 8 )$$

$${V}_{t} ( {τ}_{j} ) = {V}_{oc} ( SOC ( {τ}_{j} ) , {T}_{b} ( {τ}_{j} ) ) + {Z}_{0} ( SOC ( {τ}_{j} ) , {T}_{b} ( {τ}_{j} ) ) \cdot {I}_{cc , i} + {V}_{SEI} ( SOC ( {τ}_{j} ) , {T}_{b} ( {τ}_{j} ) , {I}_{cc , i} ) + {V}_{CT} ( SOC ( {τ}_{j} ) , {T}_{b} ( {τ}_{j} ) , {I}_{cc , i} ) \qquad ( 9 )$$

In Equations 7-9, the charging current, I_{cc,i}, is sampled according to the coarser time scale, {tᵢ}, while the inlet fluid temperature Tᵢₙₗ, and the time evolution of each of SOC, battery temperature and battery terminal voltage are now assessed using the finer time scale, {τⱼ}. This combination of different time scales is illustrated in FIG. 10, as noted above.

Equation 7 may use p_{SOC} as described previously. Equation 9 quantifies terminal voltage, using the same variables as previously discussed.

Equation 8, dealing with the temperature, has three parameters, a, b, and c related to heat transfer. Parameter a relates to the heat convection capacity of the battery thermal system, specifying the battery internal dynamics, b indicates the amount of heat removed by the circulating fluid which in turn relates to the inlet fluid temperature, and c quantifies the thermal contribution caused by the electric current through the battery. Parameter c may vary with the impedances calculated previously, such that as impedance rises so would parameter c reflecting higher resistance and thus heat generation in the battery. This dynamic model corresponds to a uniform temperature distribution model. More complex temperature distribution models may be used. Additional factors, such as heat loss to ambient, may be included in Equation 8.

The preceding examples address an optimization approach. Some examples may add further constraints on the total health degradation of the battery, or health degradation of the battery within each current step, relative to a preset value, for example. Here, Equation 1 can be simplified as shown in Equation 10:

$$g ( {\{ {I}_{cc} \}}_{i} , {\{ {T}_{b} \}}_{i} , {\{ t \}}_{i} , N ) = {min}_{{\{ {I}_{cc} \}}_{i} , {\{ {T}_{b} \}}_{i} , {\{ t \}}_{i} , N} ( {t}_{f} ) \qquad ( 10 )$$

Now the only objective of the analysis is to minimize charging time, within the noted constraints on total or step-wise health degradation. These constraints can be represented as shown in Equations 11-12:

$$( {t}_{i} - {t}_{i - 1} ) \cdot [ max ( \text{} {Z}_{CT} ( {I}_{cc , i} , SOC ( {t}_{i} ) , \text{} {T}_{b , i} ) - \text{} {\overline{Z}}_{CT} ( {I}_{cc , i} , SOC ( {t}_{i} ) , {T}_{b , i} ) , 0 ) ] \leq Δ {Z}_{CT , max} \qquad ( 11 )$$

$$( {t}_{i} - {t}_{i - 1} ) \cdot [ max ( {Z}_{SEI} ( {I}_{cc , i} , SOC ( {t}_{i} ) , {T}_{b , i} ) - {\overline{Z}}_{SEI} ( {I}_{cc , i} , SOC ( {t}_{i} ) , {T}_{b , i} ) , 0 ) ] \leq Δ {Z}_{SEI , max} \qquad ( 12 )$$

Equation 11 addresses lithium plating indirectly, and Equation 12 addresses SEI growth. The values ΔZ_{CT,max} and ΔZ_{SEI,max} are the maximum constraint violation areas per each charging period. This approach differs from that shown, for example by FIG. 9, in that the maximum penalty in any given charging period is limited, which may for example, change what would be allowable in FIG. 9 for the interval from t₀ to t₁. In some implementations one or the other of these approaches may be preferred; it is likely that the method using constraints may lead to longer charging times but less health degradation overall.

Another illustrative example may be viewed as a hybrid of the total area approach (FIG. 9) and the per-period constraints in Equations 7-12. Now the cost function of Equations 1 and/or 10 instead is represented as:

$$g ( {\{ {I}_{cc} \}}_{i} , {\{ t \}}_{i} , N , {\{ {T}_{inl} \}}_{j} , {\{ τ \}}_{j} , M ) = {min}_{{\{ {I}_{cc} \}}_{i} , {\{ t \}}_{i} , N , {\{ {T}_{inl} \}}_{j} , {\{ τ \}}_{j} , M} ( {t}_{f} ) \qquad ( 13 )$$

Here the optimization has more control variables, with the finer sampling time scale (and corresponding number of fine time samples, M), and the inlet coolant temperatures are also now optimized variables in addition to each of the charging current, coarser time scale (and corresponding number of coarse time samples N). The models used previously may be applied again. The constraints can now be stated as in terms of the finer time scale:

$$( 14 )$$

$$( {τ}_{j} - {τ}_{j - 1} ) \cdot [ max ( \text{} {Z}_{CT} ( {I}_{cc , i} , SOC ( {τ}_{j} ) , \text{} {T}_{b} ( {τ}_{j} ) ) - \text{} {\overline{Z}}_{CT} ( {I}_{cc , i} , SOC ( {τ}_{j} ) , {T}_{b} ( {τ}_{j} ) ) , 0 ) ] \leq Δ {Z}_{CT , max}$$

$$( {τ}_{j} - {τ}_{j - 1} ) \cdot [ max ( {Z}_{SEI} ( {I}_{cc , i} , SOC ( {τ}_{j} ) , {T}_{b} ( {τ}_{j} ) ) - {\overline{Z}}_{SEI} ( {I}_{cc , i} , SOC ( {τ}_{j} ) , {T}_{b} ( {τ}_{j} ) ) , 0 ) ] \leq Δ {Z}_{SEI , max} \qquad ( 15 )$$

Equation 14 indirectly limits lithium plating and Equation 15 limits SEI growth within each time step of the finer time scale. It may be noted that Equation 6 may (optionally) be adjusted to refer to the finer time scale when setting the maximum time steps, as the values of interest, including battery temperature, SOC and terminal voltage, are being updated using the finer time scale.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls. In this document, the terms “a” or “an” are used, as is common in patent documents, to include one or more than one, independent of any other instances or usages of “at least one” or “one or more.” Moreover, in the claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic or optical disks, magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, innovative subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the protection should be determined with reference to the appended claims, along with the full scope of equivalents to which such claims are entitled.

What is claimed is:

1. A method of controlling charging of a battery in an electric vehicle by a charging station, the method comprising:
the vehicle sending a set of battery parameters to an analysis system prior to charging;
the analysis system using the battery parameters to calculate a target charging current profile and a target temperature profile for a charging operation;
the analysis system sending a first set of temperature control signals to the vehicle;
the vehicle receiving the first set of temperature control signals;
with the vehicle coupled to a charging station:
the charging station issuing current to the electric vehicle to charge the battery by controlling the current to match the target charging current profile; and
the electric vehicle using the first set of temperature control signals to control a temperature of the battery.

2. The method of claim 1, wherein the set of battery parameters sent by the vehicle to the analysis system includes each of an initial battery temperature, a battery state of charge, and an impedance of the battery.

3. The method of claim 1, further comprising:
the analysis system sending a second set of temperature control signals to the electric vehicle as the battery is charged;
the electric vehicle receiving the second set of temperature control signals; and
the electric vehicle using the second set of temperature control signals to control the temperature of the battery as the battery is being charged;
wherein the electric vehicle uses the first set of temperature control signals and the second set of temperature control signals to match the target temperature profile as the battery is being charged.

4. The method of claim 1, wherein the first set of temperature control signals includes the target temperature profile, and the electric vehicle includes a battery temperature management system which controls the temperature of the battery during charging to match the target temperature profile.

5. The method of claim 1, wherein the analysis system calculates the target charging current profile and the target temperature profile by minimizing a sum of an estimated charge completion time and one or more penalties related to battery degradation, including at least a first penalty for lithium plating.

6. The method of claim 5, wherein the one or more penalties also includes a second penalty for solid electrolyte interphase (SEI) layer growth.

7. The method of claim 1, wherein the analysis system is a component of the charging station.

8. The method of claim 1, wherein the analysis system is remote from the charging station, and at least one of the electric vehicle or the charging station communicates the battery parameters to the analysis system.

9. An analyzer for determining a cycle for charging of a battery in an electric vehicle by a charging station, the analyzer comprising a controller and a controller-readable memory storing executable instructions for performing the following:
receiving a set of battery parameters from the electric vehicle prior to charging;
calculating a target charging current profile and a target temperature profile for a charging operation based on the set of battery parameters;
sending a first set of temperature control signals to the electric vehicle based on the target temperature profile; and
sending the target charging current profile to a charger controller in the charging station.

10. The analyzer of claim 9, wherein the set of battery parameters includes each of an initial battery temperature, a battery state of charge, and an impedance of the battery.

11. The analyzer of claim 9, wherein the executable instructions further include an instruction for sending a second set of temperature control signals to the electric vehicle as the battery system is charged.

12. The analyzer of claim 9, wherein the first set of temperature control signals includes the target temperature profile for use by the electric vehicle to control the temperature of the battery during charging.

13. The analyzer of claim 9, wherein the executable instructions further include instructions for calculating the target charging current profile and the target temperature profile by:
calculating one or more penalties determined for each of a plurality of charging steps, including at least a first penalty for lithium plating; and
minimizing a sum of an estimated charge completion time and the one or more penalties by manipulating charging current to be delivered in each of the plurality of charging steps.

14. The analyzer of claim 13, wherein the one or more penalties also includes a second penalty for solid electrolyte interphase (SEI) layer growth.

15. The analyzer of claim 14, wherein the first penalty is determined from a data table using temperature of the battery system, charging current, and state of charge, and the second penalty is determined from a data table using temperature of the battery system, charging current, and state of charge.

16. The analyzer of claim 14, wherein the first penalty is an explicit function of temperature of the battery system, charging current, and state of charge.

17. The analyzer of claim 14, wherein the analyzer is part of a remote server located away from the charging station, and the executable instructions are for sending the target charging current profile to a charger controller in the charging station by communicating remotely to the charger controller.

18. A charging system for an electric vehicle having therein a battery, the charging system comprising a charging architecture having a charging controller, and an analyzer as in claim 9.

19. An electric vehicle comprising:
a battery for providing driving power to the electric vehicle;
a battery thermal management system (BTMS); and
an electrochemical impedance spectroscopy (EIS) diagnostic system for performing EIS on the battery to obtain a complex impedance thereof;
a controller configured to:
control the EIS diagnostic system to perform EIS on the battery to determine a complex impedance of the battery;
in anticipation of a charging event at a charging station, send the complex impedance, a state of charge of the battery, and a temperature of the battery to an analyzer;
receive, from the analyzer one or more temperature control instructions;
control the BTMS to execute the one or more temperature control instructions during charging of the battery at the charging station.

20. The electric vehicle of claim 19, wherein the controller is further configured to:
control the BTMS to adjust the battery temperature to match a first temperature in the one or more temperature control instructions;
determine the battery is at the first temperature; and
issue a communication to the charge station indicating that the battery is ready for charging.
